(19) United States
(12) Patent Application Publication
(10) Pub. No.: US 2008/0009134 A1
(43) Pub. Date: Jan. 10, 2008

(54) Method for fabricating metal silicide

(76) Inventors: Tsung-Yu Hung, Sinshih Township (TW); Chun-Chieh Chang, Nansi Township (TW); Chao-Ching Hsieh, Tainan City (TW); Yi-Wei Chen, Dajia Township (TW); Yu-Lan Chang, Kaohsiung City (TW); Chien-Chung Huang, Ta-Chia Chen (TW)

Correspondence Address: J.C. Patents, Inc., Suite 250, 4 Venture, Irvine, CA, 92618, US

(21) Appl. No.: 11/482,604

(22) Filed: Jul. 6, 2006

(51) Int. Cl. H01L 21/4763; H01L 21/44

(52) U.S. Cl. 438/649; 438/651; 438/664; 438/655; 257/E29.161

(57) ABSTRACT

A method for fabricating a metal silicide is described. First, a silicon material layer is provided. An alloy layer is formed on the silicon material layer, and the alloy layer is made from a first metal and a second metal, wherein, the first metal is a refractory metal, and the second metal is selected from a group consisting of Pt, Pd, Mo, Ru, and Ta. A first rapid thermal process (RTP) is performed at a first temperature. A first cleaning process is performed by using a cleaning solution. A second RTP is performed at a second temperature, wherein the second temperature is higher than the first temperature. A second cleaning process is performed by using a cleaning solution including a hydrochloric acid.

### BACKGROUND OF THE INVENTION

1. Field of Invention

The present invention relates to a method for fabricating a metal silicide. More particularly, the present invention relates to a method for fabricating a metal silicide capable of suppressing the generation of junction leakage.

2. Description of Related Art

With the increasing integration of semiconductor devices, patterns and line widths in the devices are gradually reduced, which lead to the raising of the contact resistance of gates and wirings in the devices and generate a slow resistance-capacitance delay (RC Delay), and thus the operating speed of the devices is negatively affected. As the resistance of metal silicide is lower than that of polysilicon, and the thermal stability is higher than that of common interconnect material (for example, aluminum), in order to reduce the sheet resistance of the source/drain region and maintain the integrity of the shallow junction between a metal and a semiconductor device, a metal silicide can be formed on the connection interface between the gate and source/drain and the metal wires to reduce the resistance between the gate and source/drain region and the metal interconnects.

A conventional method for fabricating a metal silicide involves forming a metal layer on the semiconductor chip, and then transferring the chip into a high-temperature environment, such that a metal silicide is formed through the metal layer that covers the gate electrode or the source/drain which is in contact with the silicon material in a high-temperature environment. No metal silicide is formed on other portions since the metal layer is not in contact with the silicon material of the chip.

In the process of fabricating the above metal silicide, a residual unreacted metal is left, which negatively affects the electrical property, so the residual unreacted metal must be removed. In a conventional process for fabricating cobalt silicide, nickel silicide, or the like, the residual metal such as Co or Ni is removed by using the SPM cleaning solution or the APM cleaning solution.

At present, a metal silicide (for example, Ni—Pt metal silicide) formed by an alloy made from a refractory metal and a metal selected from a group consisting of Pt, Pd, Mo, Ru, and Ta, which can effectively reduce the occurrence of junction leakage.

However, take Ni—Pt metal silicide as an example, the Pt metal remained in the forming process cannot be removed by using the conventional SPM cleaning solution or APM cleaning solution. Therefore, it is required to develop a method for fabricating a metal silicide capable of effectively removing the residual metal such as Pt, Pd, Mo, Ru, or Ta without damaging the metal silicide.

### SUMMARY OF THE INVENTION

An objective of the present invention is to provide a method for fabricating a metal silicide capable of effectively removing the residual metal which is not fully reacted.

Another objective of the present invention is to provide a method for fabricating a metal silicide, the metal silicide fabricated is capable of reducing the occurrence of junction leakage.

The present invention provides a method for fabricating a metal silicide. First, a silicon material layer is provided. Then, an alloy layer is formed on the silicon material layer, and the alloy layer is made from a first metal and a second metal, wherein the first metal is a refractory metal and the second metal is selected from a group consisting of Pt, Pd, Mo, Ru, and Ta. Then, a first rapid thermal process (RTP) is performed at a first temperature. Next, a first cleaning process is performed by using a cleaning solution. Then, a second RTP is performed at a second temperature, wherein the second temperature is higher than the first temperature. Next, a second cleaning process is performed by using a cleaning solution including a hydrochloric acid.

According to an embodiment of the present invention, in the above-mentioned method for fabricating a metal silicide, the refractory metal is, for example, Ni, Co, or W.

According to the above method for fabricating a metal silicide described in an embodiment of the present invention, the cleaning solution including a hydrochloric acid is, for example, hydrochloric acid hydrogen peroxide mixture (HPM) cleaning solution.

According to the above method for fabricating a metal silicide described in an embodiment of the present invention, the cleaning solution used in the first cleaning process is, for example, sulfuric acid-hydrogen peroxide mixture (SPM) cleaning solution or ammonium hydrogen peroxide mixture (APM) cleaning solution.

According to the above method for fabricating a metal silicide described in an embodiment of the present invention, the content of the second metal is, for example, 1% to 15%.

According to the above method for fabricating a metal silicide described in an embodiment of the present invention, the first temperature is, for example, 280° C. to 350° C.

According to the above method for fabricating a metal silicide described in an embodiment of the present invention, the second temperature is, for example, 400° C. to 500° C.

According to the above method for fabricating a metal silicide described in an embodiment of the present invention, a pre-cleaning process is further performed to the silicon material layer before the alloy layer is formed.

According to the above method for fabricating a metal silicide described in an embodiment of the present invention, the cleaning solution used in the pre-cleaning process is, for example, dilute hydrofluoric acid (DHF) cleaning solution.

According to the above method for fabricating a metal silicide described in an embodiment of the present invention, a cap layer is further formed on the alloy layer after the alloy layer is formed and before the first rapid thermal process is performed.

According to the above method for fabricating a metal silicide described in an embodiment of the present invention, the material of the cap layer is, for example, Ti or TiN.

According to the above-mentioned method for fabricating a metal silicide described in an embodiment of the present invention, the method for forming the alloy layer is, for example, physical vapor deposition.

According to the above-mentioned method for fabricating a metal silicide described in an embodiment of the present invention, the material of the silicon material layer is, for example, monocrystalline silicon or polysilicon.

The present invention provides a method for fabricating a metal silicide. First, a silicon material layer is provided. Then, an alloy layer is formed on the silicon material layer, and the alloy layer is made from a first metal and a second metal, wherein the first metal is a refractory metal and the second metal is selected from a group consisting of Pt, Pd, Mo, Ru, and Ta. Then, a rapid thermal process is performed, and the temperature of the rapid thermal process is 330° C. to 500° C. Next, a first cleaning process is performed by using a cleaning solution. Then, a second cleaning process is performed by using a cleaning solution including a hydrochloric acid.

In view of the above, the present invention uses the cleaning solution including hydrochloric acid to clean, so the residual Pt, Pd, Mo, Ru, or Ta can be effectively removed, such that the metal silicide has a better electrical property.

In addition, the cleaning solution including hydrochloric acid is used to remove the residual Pt, Pd, Mo, Ru, or Ta after the high-temperature rapid thermal process is performed. At that time, the phase of the metal silicide has been completely transformed into a phase which has a low resistance value and is not easy to be damaged by the cleaning solution including hydrochloric acid, and thus a high-quality metal silicide can be fabricated.

In another aspect, the metal silicide fabricated according to the present invention is formed by an alloy made from a refractory metal and a metal selected from a group consisting of Pt, Pd, Mo, Ru, and Ta, thus effectively reducing the occurrence of junction leakage.

In order to make the aforementioned and other objectives, features and advantages of the present invention comprehensible, preferred embodiments accompanied with figures are described in detail below.

### BRIEF DESCRIPTION OF THE DRAWINGS

FIG. 1 is a flow chart of fabricating a metal silicide according to an embodiment of the present invention.

FIG. 2 is a flow chart of fabricating a metal silicide according to another embodiment of the present invention.

### DESCRIPTION OF EMBODIMENTS

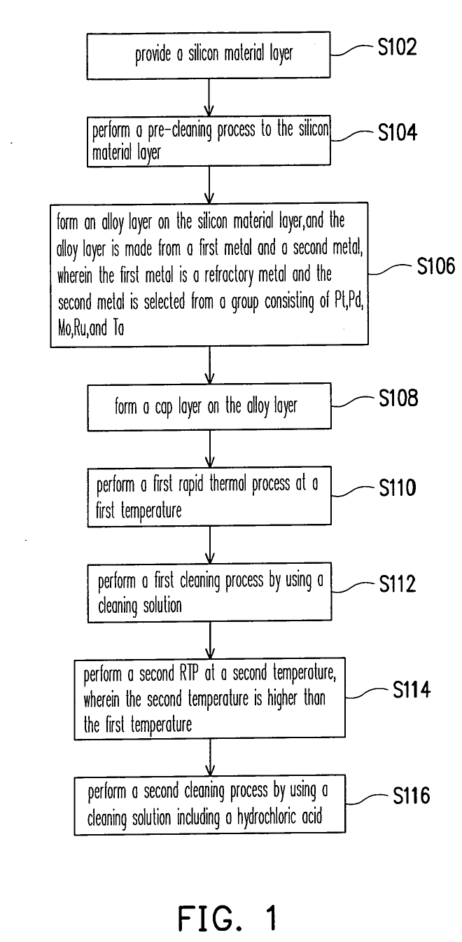

FIG. 1 is a flow chart of fabricating the metal silicide according to an embodiment of the present invention.

First, step S102 is performed, in which a silicon material layer is provided. The silicon material layer is, for example, a polysilicon material layer for forming the gate of the metal-oxide semiconductor transistor, or a monocrystalline silicon substrate for forming the source/drain region.

Next, step S104 can be selectively performed, in which a pre-cleaning process is performed to the silicon material layer to remove a native oxide layer formed on the silicon material layer. The cleaning solution used in the pre-cleaning process is, for example, DHF cleaning solution.

Then, step S106 is performed, in which an alloy layer is formed on the silicon material layer. The alloy layer is made from a first metal and a second metal, wherein the first metal is a refractory metal and the second metal is selected from a group consisting of Pt, Pd, Mo, Ru, and Ta. The method for forming the alloy layer is, for example, physical vapor deposition, such as sputtering. The content of the second metal is, for example, 1% to 15%. The refractor), metal is, for example, Ni, Co, W, or the like.

Next, step S108 can be selectively performed, in which a cap layer is formed on the alloy layer to prevent oxidation of the formed alloy layer due to the exposure to air. The material of the cap layer is, for example, Ti or TiN.

Then, step S110 is performed, in which a first rapid thermal process is performed at a first temperature to form a uniform metal silicide and fix the thickness of the metal silicide. The first temperature is, for example, 280° C. to 350° C.

Next, step S112 is performed, in which a first cleaning process is performed by using a cleaning solution to remove the cap layer and the refractory metal that is not fully reacted. The cleaning solution used in the first cleaning process is, for example, SPM cleaning solution or APM cleaning solution, wherein the SPM cleaning solution comprises sulfuric acid, hydrogen peroxide, and deionized water, and the APM cleaning solution comprises aqueous ammonia, hydrogen peroxide, and deionized water.

Then, step S114 is performed, in which a second RTP is performed at a second temperature, wherein the second temperature is higher than the first temperature, so as to completely transform the phase of the metal silicide into a phase which has a low resistance value and is not easy to be damaged by the cleaning solution including hydrochloric acid. The second temperature is, for example, 400° C. to 500° C.

Then, step S116 is performed, in which a second cleaning process is performed by using a cleaning solution including a hydrochloric acid to remove Pt, Pd. Mo, Ru, or Ta that is not fully reacted. The operating temperature when performing the second cleaning process is, for example, 50° C. to 90° C. The cleaning solution including hydrochloric acid used in the second cleaning process is, for example, HPM cleaning solution, wherein the HPM cleaning solution comprises hydrochloric acid, hydrogen peroxide, and deionized water, and the ratio of hydrochloric acid to hydrogen peroxide is, for example, 1 to 5.

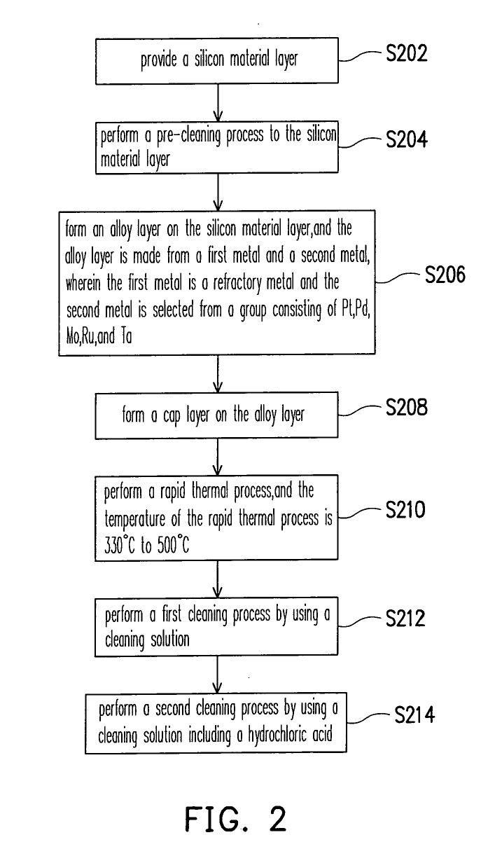

FIG. 2 is a flow chart of fabricating the metal silicide according to another embodiment of the present invention.

First, step S202 is performed, in which a silicon material layer is provided. The silicon material layer is, for example, a polysilicon material layer for forming the gate of the metal-oxide semiconductor transistor, or a monocrystalline silicon substrate for forming the source/drain region.

Next, step S204 can be selectively performed, in which a pre-cleaning process is performed to the silicon material layer to remove the native oxide layer formed on the silicon material layer. The cleaning solution used in the pre-cleaning process is, for example, DHF cleaning solution.

Then, step S206 is performed, in which an alloy layer is formed on the silicon material layer. The alloy layer is made from a first metal and a second metal, wherein the first metal is a refractory metal and the second metal is selected from a group consisting of Pt, Pd, Mo, Ru, and Ta. The method for forming the alloy layer is, for example, physical vapor deposition, such as sputtering. The content of the second metal is, for example, 1% to 15%. The refractory metal is, for example, Ni, Co W, or the like.

Next, step S208 can be selectively performed, in which a cap layer is formed on the alloy layer to prevent oxidation of the formed alloy layer due to the exposure to air. The material of the cap layer is, for example, Ti or TiN.

Then, step S210 is performed, in which a rapid thermal process is performed, and the temperature of the rapid thermal process is 330° C. to 500° C., so as to completely transform the phase of the metal silicide into a phase which has a low resistance value and is not easy to be damaged by the cleaning solution including hydrochloric acid, wherein the heating method of the rapid thermal process can be a method of heating to the desired temperature at one go, and also can be a method of two-stage heating.

Next, step S212 is performed, in which a first cleaning process is performed by using a cleaning solution to remove the cap layer and the refractory metal that is not fully reacted. The cleaning solution used in the first cleaning process is, for example, SPM cleaning solution or APM cleaning solution, wherein the SPM cleaning solution comprises sulfuric acid, hydrogen peroxide, and deionized water, and the APM cleaning solution comprises aqueous ammonia, hydrogen peroxide, and deionized water.

Then, step S214 is performed, in which a second cleaning process is performed by using a cleaning solution including a hydrochloric acid to remove Pt, Pd. Mo, Ru, or Ta which is not fully reacted. The second cleaning process is performed at a temperature of, for example, 50° C. to 90° C. The cleaning solution including hydrochloric acid used in the second cleaning process is, for example, HPM cleaning solution, wherein the HPM cleaning solution comprises hydrochloric acid, hydrogen peroxide, and deionized water, and the ratio of hydrochloric acid to hydrogen peroxide is, for example, 1 to 5.

The method for fabricating the metal silicide described in the above-mentioned embodiments can be applied to, for example, the metal-oxide semiconductor transistor device, for forming a metal silicide on the polysilicon gate or on the source/drain region in the monocrystalline silicon substrate. Thus, the metal silicide can reduce the contact resistance of the gate and wirings, thus increasing the operating speed of the metal-oxide semiconductor transistor device. In another aspect, the metal silicide can reduce the sheet resistance of the source/drain region, and maintain the integrity of the shallow junction between metal and semiconductor device. It should be noted that the metal silicide fabricated according to the present invention is formed by an alloy made from a refractory metal and a metal selected from a group consisting of Pt, Pd, Mo, Ru, and Ta, which can effectively reduce the occurrence of the junction leakage of metal-oxide semiconductor transistor device. It is obvious to those of ordinary skill in the art that the method for fabricating the metal silicide provided by the present invention can be applied to not only the metal-oxide semiconductor transistor device, but also to the processes requiring the metal silicide in the semiconductor industry.

In view of the above, the present invention has at least the following advantages.

1. The metal silicide fabricated according to the present invention is formed by an alloy made from a refractory metal and a metal selected from a group consisting of Pt, Pd, Mo, Ru, and Ta, which can effectively suppress the occurrence of junction leakage.

2. The method for fabricating a metal silicide provided by the present invention uses a cleaning solution including hydrochloric acid to clean, so the residual Pt, Pd, Mo, Ru, or Ta can be effectively removed.

3. In the method for fabricating a metal silicide provided by the present invention, when the cleaning solution including hydrochloric acid is used to remove the residual Pt, Pd, Mo, Ru, or Ta, the metal silicide will not be damaged, thus a high-quality metal silicide can be fabricated.

4. In the method for fabricating a metal silicide provided by the present invention, a pre-cleaning process can be performed to the silicon material layer to remove the native oxide layer formed on the silicon material layer, such that the metal silicide subsequently formed has a better electrical property.

5. In the method for fabricating a metal silicide provided by the present invention, a cap layer is formed on the alloy layer, thus preventing the oxidation of the formed alloy layer due to the exposure to air.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a metal silicide, comprising:
providing a silicon material layer:
forming an alloy layer on the silicon material layer, the alloy layer being made from a first metal and a second metal, wherein the first metal is a refractory metal and the second metal is selected from a group consisting of Pt, Pd, Mo, Ru, and Ta;
performing a first rapid thermal process (RTP) at a first temperature;
performing a first cleaning process by using a cleaning solution;
performing a second rapid thermal process at a second temperature, wherein the second temperature is higher than the first temperature; and
performing a second cleaning process by using a cleaning solution including hydrochloric acid.

2. The method for fabricating a metal silicide as claimed in claim 1, wherein the refractory metal is Ni, Co, or W.

3. The method for fabricating a metal silicide as claimed in claim 1, wherein the cleaning solution including hydrochloric acid comprises HPM cleaning solution.

4. The method for fabricating a metal silicide as claimed in claim 1, wherein the cleaning solution is SPM cleaning solution or APM cleaning solution.

5. The method for fabricating a metal silicide as claimed in claim 1, wherein the content of the second metal is 1% to 15%.

6. The method for fabricating a metal silicide as claimed in claim 1, wherein the first temperature is 280° C. to 350° C.

7. The method for fabricating a metal silicide as claimed in claim 1, wherein the second temperature is 400° C. to 500° C.

8. The method for fabricating a metal silicide as claimed in claim 1, further comprising performing a pre-cleaning process to the silicon material layer before forming the alloy layer.

9. The method for fabricating a metal silicide as claimed in claim 8, wherein the cleaning solution used in the pre-cleaning process comprises DHF cleaning solution.

10. The method for fabricating a metal silicide as claimed in claim 1, further comprising forming a cap layer on the alloy layer after the alloy layer is formed and before performing the first rapid thermal process.

11. The method for fabricating a metal silicide as claimed in claim 10, wherein the material of the cap layer is Ti or TiN.

12. The method for fabricating a metal silicide as claimed in claim 1, wherein the method for forming the alloy layer comprises physical vapor deposition.

13. The method for fabricating a metal silicide as claimed in claim 1, wherein the material of the silicon material layer is monocrystalline silicon or polysilicon.

14. A method for fabricating a metal silicide, comprising:
providing a silicon material layer;
forming an alloy layer on the silicon material layer, the alloy layer being made from a first metal and a second metal, wherein the first metal is a refractory metal and the second metal is selected from a group consisting of Pt, Pd, Mo, Ru, and Ta;
performing a rapid thermal process, wherein the temperature of the rapid thermal process is 330° C. to 500° C.;
performing a first cleaning process by using a cleaning solution; and
performing a second cleaning process by using a cleaning solution including hydrochloric acid.

15. The method for fabricating a metal silicide as claimed in claim 14, wherein the refractory metal is Ni, Co, or W.

16. The method for fabricating a metal silicide as claimed in claim 14, wherein the cleaning solution including hydrochloric acid comprises HPM cleaning solution.

17. The method for fabricating a metal silicide as claimed in claim 14, wherein the cleaning solution is SPM cleaning solution or APM cleaning solution.

18. The method for fabricating a metal silicide as claimed in claim 14, wherein the content of the second metal is 1% to 15%.

19. The method for fabricating a metal silicide as claimed in claim 14, further comprising performing a pre-cleaning process to the silicon material layer before forming the alloy layer.

20. The method for fabricating a metal silicide as claimed in claim 19, wherein the cleaning solution used in the pre-cleaning process comprises DHF cleaning solution.

21. The method for fabricating a metal silicide as claimed in claim 14, further comprising forming a cap layer on the alloy layer after the alloy layer is formed and before performing the rapid thermal process.

22. The method for fabricating a metal silicide as claimed in claim 21, wherein the material of the cap layer is Ti or TiN.

23. The method for fabricating a metal silicide as claimed in claim 14, wherein the method for forming the alloy layer comprises physical vapor deposition.

24. The method for fabricating a metal silicide as claimed in claim 14, wherein the material of the silicon material layer is monocrystalline silicon or polysilicon.
